(19) United States
(12) Patent Application Publication
(10) Pub. No.: US 2008/0153196 A1
(43) Pub. Date: Jun. 26, 2008

(54) Image sensor device and method of manufacturing the same

(76) Inventor: Ching-Hung Kao, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 12/042,346

(22) Filed: Mar. 5, 2008

Related U.S. Application Data
(62) Division of application No. 11/379,061, filed on Apr. 18, 2006.

(51) Int. Cl. H01L 21/339

(52) U.S. Cl. 438/75; 257/E21.457

(57) ABSTRACT

A method of manufacturing image sensor devices, in which a dielectric protecting layer is formed on a photo-receiving region before a gate of a MOS is formed. Therefore, during the subsequent processes for forming the MOS component, damage to the surface of the photo-receiving region caused by plasma or etching can be avoided, and the dark current is improved. An image sensor device manufactured by the method is also disclosed and characterized in that a part of the gate stacks over the dielectric protecting layer and the surface of the photo-receiving region is smooth to obtain good performance.

### CROSS REFERENCE TO RELATED APPLICATIONS

This application is a divisional application of U.S. patent application Ser. No. 11/379,061 filed Apr. 18, 2006, which is herein incorporated by reference in its entirety.

### BACKGROUND OF THE INVENTION

1. Field of the Invention

The present invention relates to an image sensor device and a method of manufacturing the same, and more particularly to, a CMOS image sensor device using photodiodes and a method of manufacturing the same.

2. Description of the Prior Art

CMOS image sensors (CISs) and charge-coupled devices (CCDs) are optical circuit components for utilization with light signals and representing the light signals as digital signals. CISs and CCDs are used in the prior art. These two components are widely applied to many devices, including scanners, video cameras, and digital still cameras. CCDs use is limited in the market due to price and the volume considerations. As a result, CISs enjoy greater popularity in the market. Since the CMOS image sensor device is produced using conventional semiconductor techniques, it has advantages of low cost and reduced device size. The CMOS image sensor device may be classified into a linear type and a plane type. The linear CMOS is often used in scanners and the plane CMOS is often used in digital cameras.

For the performance of a CMOS image sensor device, the dark current is an important index and unwanted. The dark current correlates to the STI (LOCOS) induced defect, plasma damage, wafer impurity, etc. occurring during the manufacturing process. For example, the photodiode layer of the CMOS image sensor device tends to be damaged during the plasma etching process, and thus, a dark current occurs.

U.S. Pat. No. 6,906,364 discloses a structure of a CMOS image sensor device to minimize the generation of dark current, which includes a photodiode sensor region, a transistor device region, a self-aligned block and a protective layer. The photodiode sensor region and the transistor device region are formed in a substrate, and a self-aligned block is formed on the photodiode sensor region. A protective layer is formed on the entire substrate, covering the self-aligned block. The photodiode sensor region is thus protected from being damaged during the subsequent backend process to minimize the generation of dark current. However, the gate electrode is formed before the protective layer is formed, and the photodiode sensor region still has a risk to be damaged during the formation of the gate electrode by a plasma etching process.

Thus, there is still a need for an image sensor device having a reduced dark current and a manufacturing method thereof.

### SUMMARY OF THE INVENTION

An object of the present invention is to provide an image sensor device having a reduced dark current.

Another object of the present invention is to provide a method of manufacturing an image sensor device to obtain an image sensor device having a reduced dark current.

The image sensor device according to the present invention comprises a substrate, a photo-receiving region, a dielectric protecting layer, a gate insulating film, a gate electrode, and a diffusion region. The photo-receiving region is in the substrate. The dielectric protecting layer is on the photo-receiving region as a protecting layer for the photo-receiving region. The gate insulating film is on the substrate and adjacent to the dielectric protecting layer. The gate electrode is on the gate insulating film and with one side on a part of the dielectric protecting layer. The diffusion region is in the substrate.

The method of manufacturing an image sensor device according to the present invention comprises the steps as follows. First, a substrate is provided. The substrate comprises a photo-receiving region. Next, a dielectric protecting layer is defined on the photo-receiving region. Subsequently, a gate insulating film is formed on the substrate and adjacent to the dielectric protecting layer. A gate electrode is defined on the gate insulating film and a side of the gate electrode is allowed to extend onto a part of the dielectric protecting layer. Finally, a diffusion region is formed in the substrate at another side of the gate electrode and a photosensing layer is formed in the photo-receiving region.

In another embodiment, the method of manufacturing an image sensor device according to the present invention comprises the steps as follows. First, a substrate comprising a photo-receiving region in the substrate is provided. Next, a dielectric protecting layer is defined on the photo-receiving region. A photosensing layer is formed in the photo-receiving region. Subsequently, a gate insulating film is formed on the substrate and adjacent to the dielectric protecting layer. A gate electrode is defined on the gate insulating film and a side of the gate electrode is allowed to extend onto a part of the dielectric protecting layer. Finally, a diffusion region is formed in the substrate at another side of the gate electrode.

In still another embodiment, the method of manufacturing an image sensor device according to the present invention comprises the steps as follows. First, a substrate comprising a photo-receiving region and a gate region in the substrate is provided. The gate region is surrounded with the photo-receiving region. Next, a dielectric protecting layer is defined on the photo-receiving region. A diffusion region is formed in the substrate of the gate region. Subsequently, a gate insulating film is formed on the substrate of the gate region and adjacent to the dielectric protecting layer. A gate electrode is defined on the gate insulating film and a periphery of the gate electrode is allowed to extend onto a part of the dielectric protecting layer. Finally, a photosensing layer is formed in the photo-receiving region.

In still another embodiment, the method of manufacturing an image sensor device according to the present invention comprises the steps as follows. First, a substrate comprising a photo-receiving region and a gate region in the substrate is provided. The gate region is surrounded with the photo-receiving region. Next, a dielectric protecting layer is defined on the photo-receiving region. A photosensing layer is formed in the photo-receiving region and a diffusion region is formed in the substrate of the gate region. Subsequently, a gate insulating film is formed on the substrate and adjacent to the dielectric protecting layer. Finally, a gate electrode is defined on the gate insulating film and a periphery of the gate electrode is allowed to extend onto a part of the dielectric protecting layer.

The image sensor device according to the present invention is manufactured through forming a dielectric protecting layer on the photo-receiving region as a protecting layer, and subsequently forming a gate electrode on the substrate. Especially, the gate electrode is formed with one side to extend onto a part of the dielectric protecting layer. Consequently, the dielectric protecting layer may protect the photosensing layer in the photo-receiving region to minimize damages caused by resist removal, gate etching, and spacer etching performed by plasma to solve the dark current problem. Furthermore, in another embodiment according to the present invention, the gate electrode is placed in a region surrounded with the photo-receiving region to contact little of the border of STI to reduce the STI induced defect for minimization of the current leakage (that is, dark current). In addition, when the gate electrode does not contact the STI border, the STI narrow width effect does not occur and thus a shielding under the gate electrode will not be formed to affect the charge transfer from the photo-receiving region. Therefore, the image sensor device according to the present invention has a good performance.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view of an embodiment of the image sensor device according to the present invention.

FIG. 2 is a schematic cross sectional view along the line AA′ shown in FIG. 1.

FIG. 3 is a schematic top view of another embodiment of the image sensor device according to the present invention.

FIG. 4 is a schematic cross sectional view along the line BB′ shown in FIG. 3.

FIGS. 5 to 8 illustrate an embodiment of the method of manufacturing an image sensor device according to the present invention.

FIGS. 9 to 13 illustrate another embodiment of the method of manufacturing an image sensor device according to the present invention.

FIGS. 14 to 15 illustrate further another embodiment of the method of manufacturing an image sensor device according to the present invention.

FIG. 16 illustrates still another embodiment of the method of manufacturing an image sensor device according to the present invention.

### DETAILED DESCRIPTION

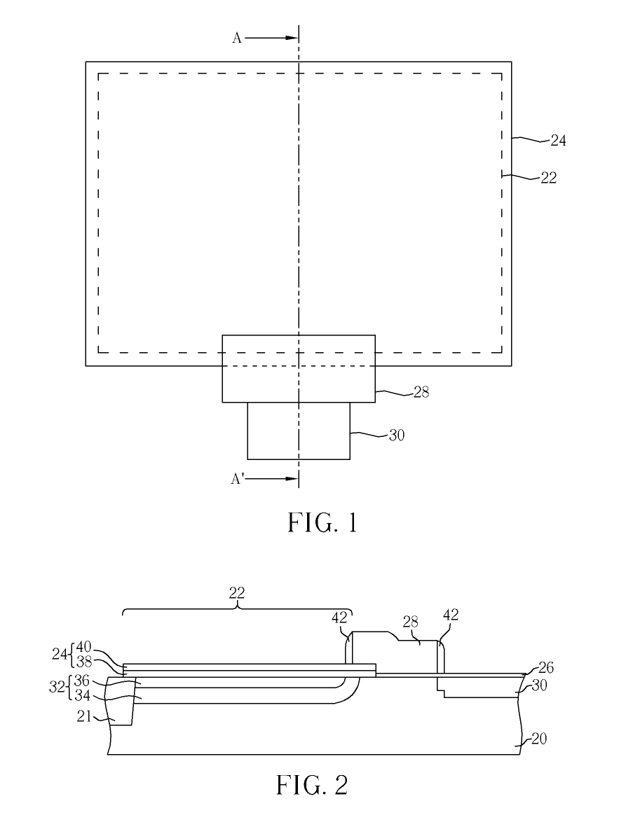

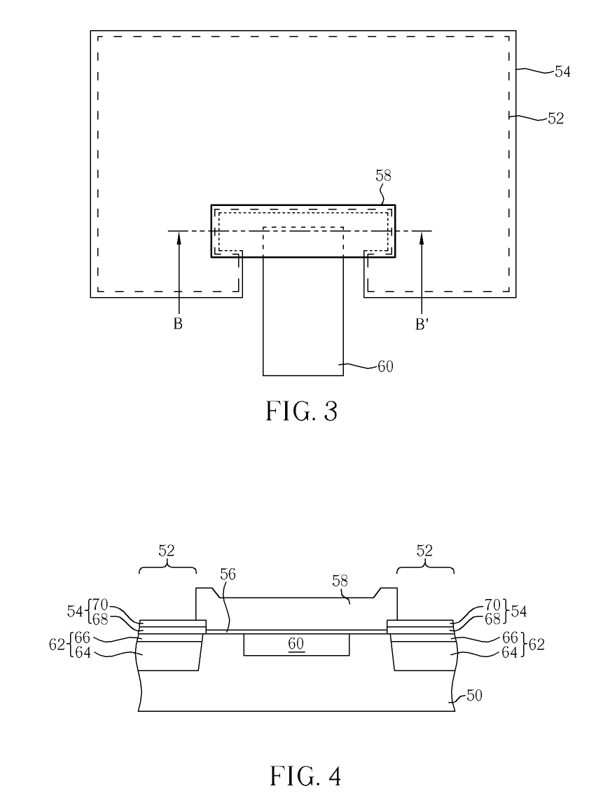

Please refer to FIGS. 1 and 2. FIG. 2 shows a schematic cross sectional view along the line AA′ in FIG. 1. The image sensor device according to the present invention may be a CMOS image sensor device comprising a substrate 20, a photo-receiving region 22, a dielectric protecting layer 24, a gate insulating film 26, a gate electrode 28, and a diffusion region 30. The image sensor device is separated form other elements with the shallow trench isolation structure 21. Other isolation, such as LOCOS, is also useful for the image sensor device according to the present invention.

The substrate 20 may be a p-type or an n-type semiconductor substrate. The photo-receiving region 22 is positioned in the substrate 20. The photo-receiving region 22 may comprise a photosensing layer 32 made of a photosensing material. For example, when the substrate 20 is a p-type substrate, the photosensing layer 32 may comprise an n-type lightly doped layer 34 and a p-type heavily doped layer 36. PIN (p-type-intrinsic-n-type) photodiode, APD photodiode, or other general photodiode may be used as the photosensing layer, but it is not limited to these materials.

The dielectric protecting layer 24 is on the photo-receiving region 22, especially on the photosensing layer 32, as a protecting layer. The dielectric protecting layer may be a single layer or a multi-layered dielectric layer. The single layer may be a dielectric material layer, for example a silicon oxide layer, etc. The multi-layered dielectric layer may be for example a silicon oxide layer 38 and a silicon nitride layer 40 on the silicon oxide layer, or a plurality of silicon oxide layers and a plurality of silicon nitride layers alternatively stacked. The dielectric protecting layer serves to protect the photo-receiving region from being damaged in backend processes, such as plasma processes. The thickness of the dielectric protecting layer may be a thickness to attain a function of protection but not affecting the transmission of the incoming light. A preferred total thickness is not more than 1000 Å. For example, in case a silicon oxide layer is used, the thickness may be from 50 Å to 1000 Å. In case a silicon nitride layer is used, the thickness may be from 50 Å to 1000 Å. When the dielectric protecting layer has a proper thickness, for example, 300 Å to 500 Å, it may further have a function of anti-reflection.

The gate insulating film 26 is positioned on the substrate 20 and adjacent to the dielectric protecting layer 24. The gate insulating film may be a gate oxide layer having a thickness preferably less than 120 Å. The gate electrode 28 is positioned on the gate insulating film 26 and with one side extending onto a part of the dielectric protecting layer 24. The gate electrode 28 comprises an electric conducting material, such as, polysilicon. A spacer 42 may be further formed on a sidewall of the gate electrode 28. The spacer may be a silicon oxide layer or a multi-layered dielectric layer. The diffusion region 30 is in the substrate 20 at another side of the gate electrode 28. The diffusion region may serve as a drain or a source in the transistor and may comprise one part of a lightly doped region and the other part of a heavily doped region with electricity same as that of the lightly doped layer 34 and the heavily doped layer 36 of the photodiode.

The image sensor device according to the present invention has a main feature that the photosensing layer of the photo-receiving region is protected by a dielectric protecting layer as a protecting layer and the gate electrode has one side extending onto a part of the dielectric protecting layer. Thus, the relative positions for the photosesing region, the gate electrode, and the diffusion region are not particularly limited, as long as the photo-receiving region and the diffusion region do not directly contact with the gate electrode. Consequently, the diffusion region may be located in the substrate at another side of the gate electrode, or have one part in the substrate under the gate electrode, and the shape of the diffusion region is not particularly limited.

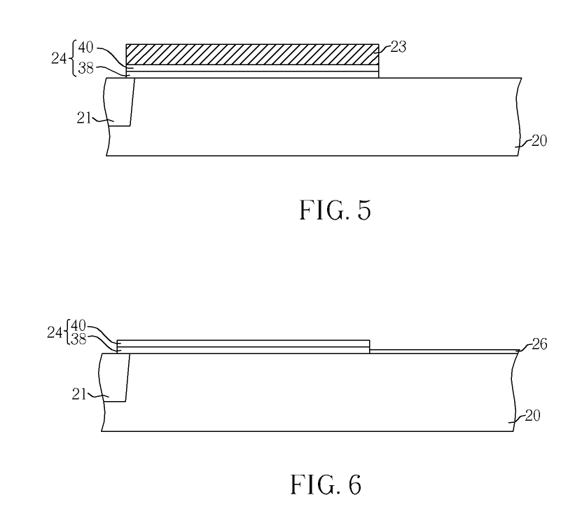

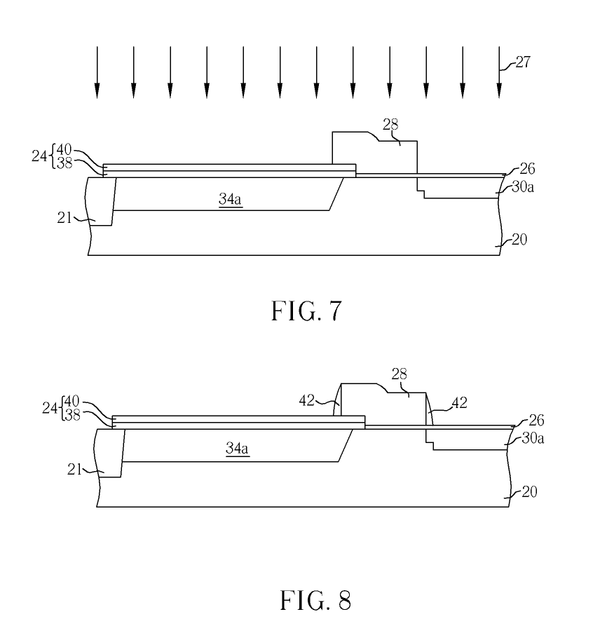

Alternatively, the region of the gate electrode may be surrounded with the photo-receiving region. For example, FIG. 3 shows another embodiment of the image sensor device according to the present invention, and FIG. 4 shows a schematic cross sectional view along the line BB′ in FIG. 3. The gate electrode 58 is positioned in the region of the substrate surrounded with the photo-receiving region 52 and with a periphery extending onto a part of the dielectric protecting layer 54, and the diffusion region 60 is partly in the substrate under the gate electrode 58. The dielectric protecting layer 54 comprises a silicon oxide layer 68 and a silicon nitride layer 70 as a protecting layer on a photosensing layer 62. The photosensing layer 62 may include a lightly doped layer 64 and a heavily doped layer 66. The gate insulating film 56 is positioned on the substrate 50 and adjacent to the dielectric protecting layer 54. The gate electrode 58 is positioned on the gate insulating film 56 with a periphery extending onto a part of the dielectric protecting layer 54. The diffusion region 60 is positioned in the substrate 50 under the gate electrode 58. The diffusion region 60 may be partly in the substrate 50 under the gate electrode 58, or in the substrate 50 at the side of the gate electrode 58 and not under the gate electrode. The advantage for such layout that the gate electrode is in the region surrounded with the photo-receiving region is that the gate electrode will not or only a little contact the border of STI or LOCOS, and thus the gate electrode is not affected by the STI induced defect, such that the dark current is reduced. Furthermore, when the gate electrode does not contact the border of STI, the STI narrow width effect will not occur and thus a shielding under the gate electrode will not be formed to retard the charge transfer from the photo-receiving region.

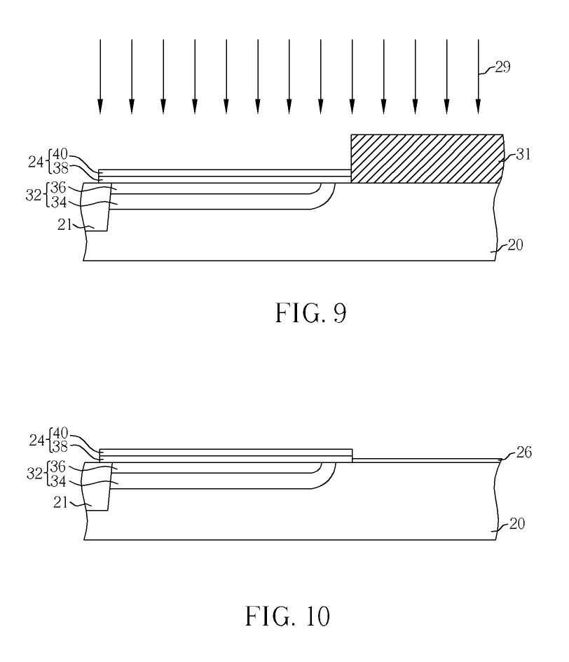

FIGS. 5 to 8 show an embodiment of the method of manufacturing an image sensor device according to the present invention. Referring to FIG. 5, first, a substrate 20 having STI 21 prepared thereon and a photo-receiving region (not shown) is provided. A silicon oxide layer may be formed on the substrate surface by a thermal oxidation, and a silicon nitride layer is formed on the silicon oxide layer using silane and ammonia gas as working gases by a plasma enhanced chemical vapor deposition, to form a dielectric material layer. The process can be repeated for several times to form a multi-layered dielectric material layer, if desired. Thereafter, a photoresist 23 has a corresponding pattern is formed using a microlithography process to shield the region of the predetermined dielectric protecting layer area corresponding to the photo-receiving region, and an etching process is performed to remove the unshielded portion of the dielectric material layer. The etching for the silicon nitride may be a dry etching, such as a plasma etching. The etching for the silicon oxide may be a dry etching or a wet etching. Accordingly, a dielectric protecting layer 24 comprising a silicon oxide layer 38 and a silicon nitride layer 40 covering the photo-receiving region is defined. Thereafter, the photoresist layer is removed.

Referring to FIG. 6, a gate oxide layer process, such as a thermal oxidation process, is performed to form an oxide layer on the substrate 20 as the gate insulating film 26 adjacent to the dielectric protecting layer 24. A well (not shown), as desired, may be further formed on the substrate 20 before the gate insulating film 26 is formed.

Referring to FIGS. 7 and 8, a conductive layer, such as a polysilicon layer or a polycide layer, is formed using a chemical vapor deposition process, and thereafter a microlithography and an etching processes are performed to form the gate electrode 28 from the conductive layer on the gate insulating film 26. The gate electrode 28 has a side extending onto a part of the dielectric protecting layer 24. Since the edge of the gate electrode thus formed is on the dielectric protecting layer as the protecting layer for the photo-receiving region, the photosensing layer will not be damaged during the formation of the gate electrode by etching the conductive layer using such as plasma or the removal of the photoresist layer on the gate electrode by etching. Thereafter, processes for forming the diffusion region and the photosensing layer are performed. For example, an ion implantation 27 is performed using the gate electrode 28 as a mask to implant ions into the substrate 20, to form a light doped region 30a. An ion implantation is also performed on the substrate in the photo-receiving region to form a lightly doped region 34a. The electricity of n-type or p-type for the light doping depends on the p-type or n-type dopants in the substrate 20. The examples for n-type dopant may be phosphorous or arsenic. The examples for p-type dopant may be boron.

A spacer 42 may be further formed on the sidewall of the gate electrode 28 through, for example, a chemical vapor deposition to form a silicon oxide layer on the substrate 20 and an anisotropic etching process to form the spacer. Thereafter, a heavier ion implantation may be performed to form a heavily doped region (not shown) in the substrate 20 at a side of spacer 42 and form a heavily doped region in the photo-receiving region 22. Thus, an image sensor device as shown in FIGS. 2 and 3 can be obtained.

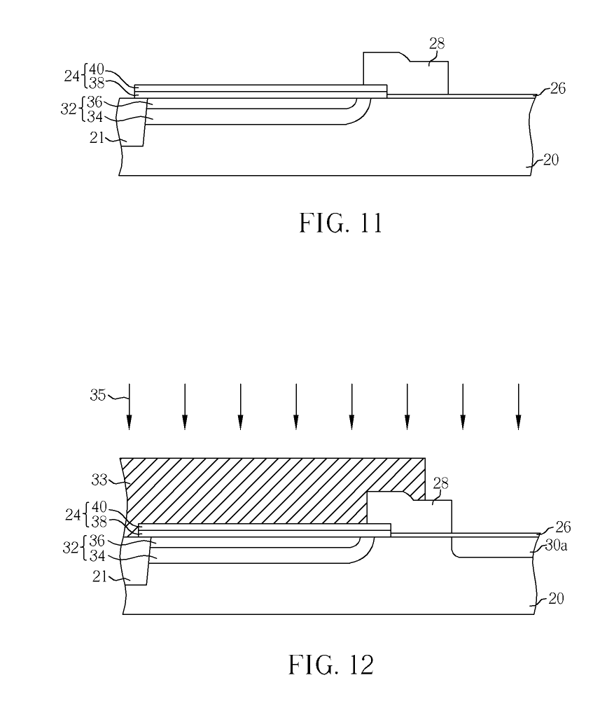

Referring to FIGS. 9 to 13, in another embodiment according to the present invention, the photosensing layer may be produced after the dielectric protecting layer is formed. FIG. 9 shows an ion implantation process 29 may be performed after the dielectric protecting layer 24 is defined, using a photoresist layer 31 as a mask, to form a lightly doped layer 34 in the photo-receiving region and further a heavily doped layer 36 in the top portion of the lightly doped layer, both combined to form a photosensing layer 32. FIG. 10 shows a gate insulating film 26 formed and adjacent to the dielectric protecting layer 24 after the photoresist layer is removed. FIG. 11 shows a gate electrode 28 is defined as describe above on the gate insulating film 26. The gate electrode 28 has a side extending onto a part of the dielectric protecting layer 24. Thus, the photosensing layer 32 under the dielectric protecting layer 24 can be protected during subsequent processes.

FIG. 12 shows the manufacturing of the diffusion region. A photo-receiving region is shielded by a patterned photoresist layer 33, and a light ion implantation 35 is performed on the substrate to form a lightly doped region 30a. Referring to FIG. 13, a spacer 42 is formed as described above, and a heavy ion implantation is performed to form a heavily doped region in a portion of the lightly doped region, to form a diffusion region 30. Thereafter, the photoresist layer 33 is removed to attain an image sensor device as shown in FIGS. 1 and 2.

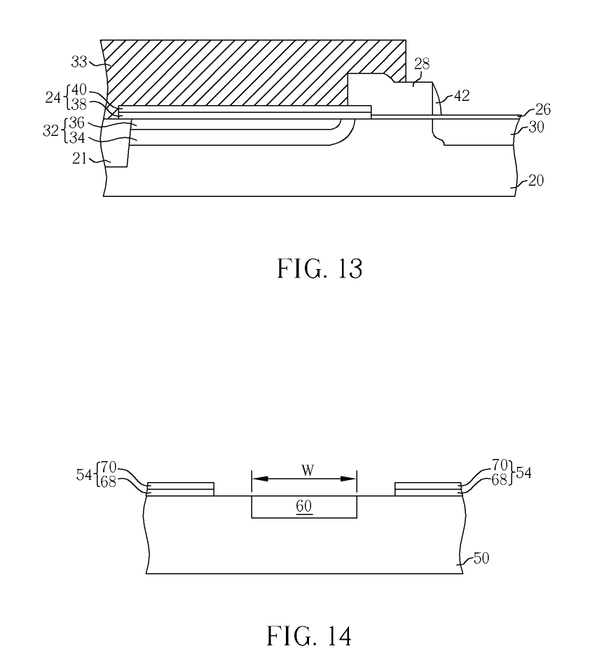

In the embodiment that the image sensor device according to the present invention has a layout as shown in FIGS. 3 and 4, since the diffusion region 60 is partly under the gate electrode 58, it is necessary to form the diffusion region 60 before the step of forming the gate electrode 58, as shown in FIGS. 14 and 15. FIG. 14 shows the dielectric protecting layer 54 comprising a silicon oxide layer 68 and a silicon nitride 70 defined on the photo-receiving region. An ion implantation process may be performed using a patterned photoresist layer as a mask to form a diffusion region 60. The width of the gate electrode 58 is decided by the width (W) of the diffusion region and the pattern defined for the photo-receiving region 52. Subsequently, as shown in FIG. 15, the gate insulating film 56 is formed on the substrate 50 and the diffusion region 60. Then, the gate electrode 58 is formed on the gate insulating film 56 with a periphery extending onto a part of the dielectric protecting layer 54. Finally, an ion implantation process is performed such that the lightly doped layer 64 and heavily doped layer 66, serving as the photosensing layer 62, are formed by performing a light ion implantation and a heavy ion implantation on the photo-receiving region, to obtain the image sensor device as shown in FIGS. 3 and 4.

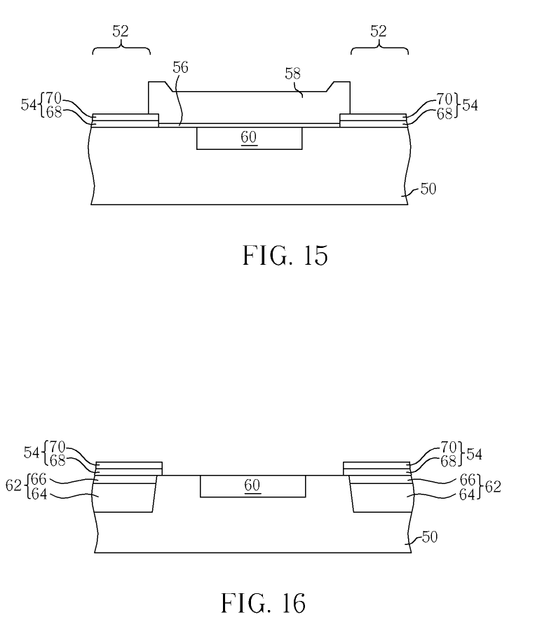

In another embodiment, the diffusion region 60 and the photosensing layer may be formed before the gate electrode 58 is formed. As shown in FIG. 16, the dielectric protecting layer 54 comprising a silicon oxide layer 68 and a silicon nitride layer 70 has been defined on the photo-receiving region. A diffusion region 60 (may include lightly doped region and heavily doped region) and a photosensing layer 62 (may include a lightly doped layer 64 and a heavily doped layer 66) are formed using an ion implantation process. Subsequently, a gate insulating film 56 is formed on the substrate 50 and the diffusion region 60. Then, the gate electrode 58 is formed with a periphery extending to a part of the dielectric protecting layer 54, and the image sensor device as shown in FIGS. 3 and 4 can be attained.

All combinations and sub-combinations of the above-described features also belong to the present invention. Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of manufacturing an image sensor device, comprising the steps of:
providing a substrate comprising a photo-receiving region in the substrate;
defining a dielectric protecting layer on the photo-receiving region;
forming a gate insulating film on the substrate and adjacent to the dielectric protecting layer;
defining a gate electrode on the gate insulating film and allowing a side of the gate electrode to extend onto a part of the dielectric protecting layer; and
forming a diffusion region in the substrate at another side of the gate electrode and a photosensing layer in the photo-receiving region.

2. The method of claim 1, wherein the step of defining a dielectric protecting layer on the photo-receiving region comprising:
forming a dielectric material layer on the substrate and covering the photo-receiving region; and
removing a part of the dielectric material layer using a microlithography process and an etching process.

3. The method of claim 1, wherein the step of defining a dielectric protecting layer on the photo-receiving region is to define a multi-layered dielectric layer.

4. The method of claim 3, wherein the multi-layered dielectric layer comprises a silicon oxide layer and a silicon nitride layer on the silicon oxide layer.

5. The method of claim 2, wherein the step of forming a dielectric material layer is to form a silicon oxide layer and to form a silicon nitride layer.

6. The method of claim 5, wherein the step of removing a part of the dielectric material layer using a microlithography process and an etching process comprises:
defining a photoresist pattern to cover the photo-receiving region;
performing a dry etching process to remove the silicon nitride layer;
performing a wet etching process to remove the silicon oxide layer; and
removing the photoresist pattern.

7. The method of claim 2, wherein the step of forming a dielectric material layer comprises a plurality of steps of alternatively forming a silicon oxide layer and forming a silicon nitride layer.

8. The method of claim 1, before the step of forming a gate insulating film on the substrate and adjacent to the dielectric protecting layer, further forming a well in the substrate.

9. The method of claim 1, wherein the step of forming a diffusion region in the substrate at another side of the gate electrode and a photosensing layer in the photo-receiving region comprises:
forming a lightly doped region in the substrate and forming a lightly doped layer in the photo-receiving region using a light ion implantation process;
forming a spacer on a side of the gate electrode; and
forming a heavily doped region in the top of the lightly doped region and forming a heavily doped layer in the top portion of the lightly doped layer using a heavy ion implantation process.

10. A method of manufacturing an image sensor device, comprising the steps of:
providing a substrate comprising a photo-receiving region in the substrate;
defining a dielectric protecting layer on the photo-receiving region;
forming a photosensing layer in the photo-receiving region;
forming a gate insulating film on the substrate and adjacent to the dielectric protecting layer;
defining a gate electrode on the gate insulating film and allowing a side of the gate electrode to extend onto a part of the dielectric protecting layer; and
forming a diffusion region in the substrate at another side of the gate electrode.

11. The method of claim 10, wherein the step of defining a dielectric protecting layer on the photo-receiving region comprising:
forming a dielectric material layer on the substrate and covering the photo-receiving region; and
removing a part of the dielectric material layer using a microlithography process and an etching process.

12. The method of claim 11, wherein the step of forming a dielectric material layer is to form a silicon oxide layer and to form a silicon nitride layer.

13. The method of claim 12, wherein the step of removing a part of the dielectric material layer using a microlithography process and an etching process comprises:
defining a photoresist pattern to cover the photo-receiving region;
performing a dry etching process to remove the silicon nitride layer;
performing a wet etching process to remove the silicon oxide layer; and
removing the photoresist pattern.

14. The method of claim 10, wherein the step of forming a diffusion region in the substrate at another side of the gate electrode comprises:
forming a lightly doped region in the substrate using a light ion implantation process;
forming a spacer on a side of the gate electrode; and
forming a heavily doped region in a top portion of the lightly doped region using a heavy ion implantation process.

15. The method of claim 10, wherein the step of forming a photosensing layer in the photo-receiving region comprises:
forming a lightly doped layer in the photo-receiving region using a light ion implantation process; and
forming a heavily doped layer in a top portion of the lightly doped layer using a heavy ion implantation process.

16. A method of manufacturing an image sensor device, comprising the steps of:
providing a substrate comprising a photo-receiving region and a gate region in the substrate, wherein the gate region is surrounded with the photo-receiving region;
defining a dielectric protecting layer on the photo-receiving region;
forming a diffusion region in the substrate of the gate region;
forming a gate insulating film on the substrate of the gate region and adjacent to the dielectric protecting layer;
defining a gate electrode on the gate insulating film and allowing a periphery of the gate electrode to extend onto a part of the dielectric protecting layer; and
forming a photosensing layer in the photo-receiving region.

17. A method of manufacturing an image sensor device, comprising the steps of:
providing a substrate comprising a photo-receiving region and a gate region in the substrate, wherein the gate region is surrounded with the photo-receiving region;
defining a dielectric protecting layer on the photo-receiving region;
forming a photosensing layer in the photo-receiving region and a diffusion region in the substrate of the gate region;
forming a gate insulating film on the substrate and adjacent to the dielectric protecting layer; and
defining a gate electrode on the gate insulating film and allowing a periphery of the gate electrode to extend onto a part of the dielectric protecting layer.
